(19) United States
(12) Patent Application Publication
(10) Pub. No.: US 2020/0135909 A1
(43) Pub. Date: Apr. 30, 2020

(54) SEMICONDUCTOR DEVICE

(71) Applicant: ROHM CO., LTD., Ukyo-ku (JP)

(72) Inventor: Taketoshi TANAKA, Ukyo-ku (JP)

(21) Appl. No.: 16/665,501

(22) Filed: Oct. 28, 2019

(30) Foreign Application Priority Data
Oct. 30, 2018 (JP) 2018-204167
Oct. 15, 2019 (JP) 2019-188671

(51) Int. Cl. H01L 29/778; H01L 29/20

(52) U.S. Cl. CPC H01L 29/7786; H01L 29/2003

(57) ABSTRACT

A semiconductor devices includes: a conductive substrate; an electron transit layer arranged on the conductive substrate; an electron supply layer arranged on the electron transit layer; and a source electrode, a drain electrode, and a gate electrode arranged on the electron supply layer, wherein the electron transit layer includes a nitride semiconductor layer including an acceptor type impurity, and wherein the semiconductor device has a characteristic that when a negative bias is applied to the conductive substrate, a source-drain resistance decreases over time.

### CROSS-REFERENCE TO RELATED APPLICATION(S)

This application is based upon and claims the benefit of priority from Japanese Patent Application No. 2018-204167, filed on Oct. 30, 2018, and Japanese Patent Application No. 2019-188671, filed on Oct. 15, 2019, the entire contents of which are incorporated herein by reference.

### TECHNICAL FIELD

The present disclosure relates to a semiconductor device, for example, a nitride semiconductor device made of a group III nitride semiconductor (hereinafter, simply referred to as a “nitride semiconductor”).

### BACKGROUND

A group III nitride semiconductor is a semiconductor using nitrogen as a group V element in a group III-V semiconductor. Aluminum nitride (AlN), gallium nitride (GaN), and indium nitride (InN) are representative examples. Generally, it may be expressed as AlₓIn_{y}Ga_{1-x-y}N (0≤x≤1, 0≤y≤1, 0≤x+y≤1). A high electron mobility transistor (HEMT) using such a nitride semiconductor has been proposed. Such HEMT includes, for example, an electron transit layer constituted by GaN and an electron supply layer constituted by AlGaN epitaxially grown on the electron transit layer. A pair of source electrode and drain electrode is formed so as to be in contact with the electron supply layer, and a gate electrode is arranged therebetween. Due to polarization caused by lattice mismatch between GaN and AlGaN, a two-dimensional (2D) electron gas is formed in the electron transit layer at a position of several A inside from an interface between the electron transit layer and the electron supply layer. The source electrode and the drain electrode are connected using this 2D electron gas as a channel. When the 2D electron gas is cut off by applying a control voltage to the gate electrode, the source and the drain are cut off from each other. When the control voltage is not applied to the gate electrode, since the source and the drain are electrically connected, the device becomes a normally-on type device.

In the related art, a normally-off type nitride semiconductor HEMT is known. In the related art, a configuration is known in which a p-type GaN layer is stacked on an AlGaN electron supply layer, a gate electrode is arranged thereon, and a channel is eliminated by a depletion layer spreading from the p-type GaN layer, thereby achieving normally-off.

In the related art, an oxide film having an interface continuous with an interface between the electron supply layer and an electron transit layer is formed on the electron transit layer. Further, a gate electrode faces the electron transit layer with the oxide film interposed therebetween. In such configuration, since the electron supply layer does not exist just under the gate electrode, a 2D electron gas is not formed just under the gate electrode, thereby achieving normally-off. The oxide film is formed by, for example, thermally oxidizing a part of the electron supply layer.

### SUMMARY

Current collapse is a problem of devices using nitride semiconductors. The current collapse is a phenomenon in which channel resistance rises and drain current is reduced (on-resistance rises) by applying a stress of a large current and a high voltage to a device. Some embodiments of the present disclosure provide a semiconductor device capable of suppressing current collapse.

According to an embodiment of the present disclosure, there is provided a semiconductor device. The device includes: a conductive substrate; an electron transit layer arranged on the conductive substrate; an electron supply layer arranged on the electron transit layer; and a source electrode, a drain electrode, and a gate electrode arranged on the electron supply layer, wherein the electron transit layer includes a nitride semiconductor layer including an acceptor type impurity, and wherein the semiconductor device has a characteristic that when a negative bias is applied to the conductive substrate, a source-drain resistance decreases over time.

According to an embodiment of the present disclosure, there is provided a semiconductor device. The device includes: a substrate; an electron transit layer arranged on the substrate; an electron supply layer arranged on the electron transit layer; and a source electrode, a drain electrode, and a gate electrode arranged on the electron supply layer, wherein the electron transit layer includes a nitride semiconductor layer including an acceptor type impurity, and wherein a deep donor density of the nitride semiconductor layer is larger than a deep acceptor density of the nitride semiconductor layer.

In some embodiments, the electron transit layer may include the nitride semiconductor layer, and a conduction path forming layer which is formed between the nitride semiconductor layer and the electron supply layer and whose surface is in contact with the electron supply layer. In some embodiments, an activation energy of a temperature characteristic of a source-drain resistance change rate is 0.5 eV or more and 0.7 eV or less.

In some embodiments, a deep donor level of the nitride semiconductor layer may be within a range of 0.5 eV or more and 0.7 eV or less from a conduction band. In some embodiments, the acceptor type impurity may be carbon, and a carbon density of the nitride semiconductor layer may be 1×10¹⁹ cm⁻³ or more and 8×10¹⁹ cm⁻³ or less. In some embodiments, the nitride semiconductor layer may include a vacancy defect VGa(VN)n including one gallium vacancy and two nitrogen vacancies.

According to an embodiment of the present disclosure, there is provided a semiconductor device. The device includes: a substrate; an electron transit layer arranged on the substrate; an electron supply layer arranged on the electron transit layer; and a source electrode, a drain electrode, and a gate electrode arranged on the electron supply layer, wherein the electron transit layer includes a nitride semiconductor layer including an acceptor type impurity, and wherein the acceptor type impurity is carbon, and a carbon density of the nitride semiconductor layer is 1×10¹⁹ cm⁻³ or more and 8×10¹⁹ cm⁻³ or less.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1A is a plan view for explaining a configuration of a semiconductor device according to an embodiment of the present disclosure.

FIG. 1B is a cross-sectional view taken along line IB-IB in FIG. 1A.

FIG. 2A is a schematic diagram for explaining a level in a band gap of DA-rich GaN, and FIG. 2B is a schematic diagram for explaining a level in the band gap of DD-rich GaN.

FIG. 3 is a schematic cross-sectional view illustrating a simulation model.

FIGS. 4A and 4B are graphs illustrating simulation results when an electron transit layer is set to DA-rich, with FIG. 4A being a graph illustrating a temporal change in distribution of a conduction band lower end energy Ec to a depth of the electron transit layer and FIG. 4B being a graph illustrating a temporal change in a source-drain current IDS.

FIG. 5A and FIG. 5B are graphs illustrating simulation results when the electron transit layer is set to DD-rich, with FIG. 5A being a graph illustrating a temporal change in distribution of a conduction band lower end energy Ec to a depth of the electron transit layer and FIG. 5B being a graph illustrating a temporal change in a source-drain current IDS.

FIG. 6 is a cross-sectional view illustrating a configuration of a sample.

FIG. 7 is a graph illustrating an experimental result when an experiment for measuring a source-drain current IDS is performed on three samples.

FIG. 8 is a graph illustrating an experimental result when an experiment for measuring a source-drain current IDS is performed on a third sample under a plurality of temperature environments.

FIG. 9 is a graph illustrating a straight line obtained by performing an Arrhenius plotting on a time constant τ to an ambient temperature T.

FIG. 10 is a graph illustrating an experimental result when an experiment for measuring an on-resistance is performed on each sample.

FIG. 11 is a graph illustrating an experimental result when an experiment for measuring a vertical leakage current is performed on each sample.

FIG. 12 is a graph illustrating a result of measuring an S parameter by a positron annihilation method for GaN samples having different carbon densities.

FIG. 13 is a cross-sectional view illustrating a configuration example of a normally-off type semiconductor device to which the present disclosure is applied.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

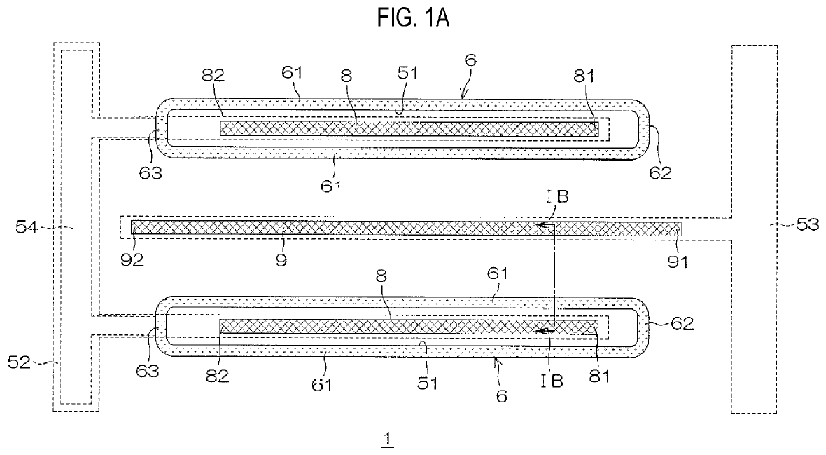

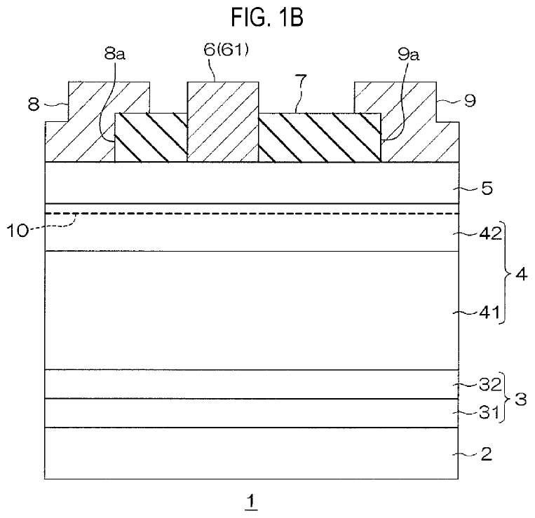

FIG. 1A is a plan view illustrating a configuration of a semiconductor device according to an embodiment of the present disclosure. FIG. 1B is a cross-sectional view taken along line IB-IB in FIG. 1A. Referring to FIG. 1B, a semiconductor device 1 includes a substrate 2, a buffer layer 3 formed on a surface of the substrate 2, an electron transit layer 4 constituted by a nitride semiconductor layer epitaxially grown on the buffer layer 3, an electron supply layer 5 constituted by a nitride semiconductor layer epitaxially grown on the electron transit layer 4, and a gate electrode 6 formed on the electron supply layer 5.

In addition, the semiconductor device 1 includes a passivation film 7 configured to cover a surface of the electron supply layer 5 and a part of both side surfaces of the gate electrode 6. Further, the semiconductor device 1 includes a source electrode 8 and a drain electrode 9 which are in ohmic contact with the electron supply layer 5 through a source electrode contact hole 8a and a drain electrode contact hole 9a formed in the passivation film 7. The source electrode 8 and the drain electrode 9 are arranged so as to sandwich the gate electrode 6 at an interval.

Referring to FIG. 1A, in the present embodiment, a plurality (two in FIG. 1A) of source electrodes 8 are arranged on the electron supply layer 5 at intervals, with each source electrode 8 being surrounded by the gate electrodes 6. The drain electrode 9 is arranged in a region between the source electrodes 8 surrounded by the gate electrodes 6. Each source electrode 8 extends in a line shape having a first end 81 and a second end 82. The gate electrode 6 is formed in an annular shape along an outer periphery of the source electrode 8. For example, the gate electrode 6 may be formed in an annular shape integrally having a pair of line-shaped finger portions 61 extending in parallel with each other, and a first connection portion 62 and a second connection portion 63 which connect ends of the finger portions 61 to each other, with the source electrode 8 interposed therebetween. Thus, the source electrode 8 may be arranged in a long closed region 51 inside the gate electrode 6.

The drain electrode 9 extends in a line shape having a first end 91 and a second end 92. The first end 91 of the drain electrode 9 is an end on the same side as the first end 81 of the source electrode 8 and the first connection portion 62 of the gate electrode 6, and the second end 92 of the drain electrode 9 is an end on the same side as the second end 82 of the source electrode 8 and the second connection portion 63 of the gate electrode 6. In the present embodiment, the drain electrode 9 is formed longer than the finger portions 61 of the gate electrode 6. The first end 91 of the drain electrode 9 may protrude from the first connection portion 62 of the gate electrode 6. Also, the second end 92 of the drain electrode 9 may protrude from the second connection portion 63 of the gate electrode 6.

A source wiring 52, a drain wiring 53, and a gate wiring 54 are connected to the source electrode 8, the drain electrode 9, and the gate electrode 6, respectively. For example, the source wiring 52 and the gate wiring 54 may be led out to the second end 92 side of the drain electrode 9. For example, the drain wiring 53 may be led out to an opposite side of the lead-out side of the source wiring 52 and the gate wiring 54 (i.e., to the side of the first end 91 of the drain electrode 9).

Returning to FIG. 1B, the substrate 2 may be, for example, a low-resistance silicon substrate. The low-resistance silicon substrate may have an impurity concentration of, for example, 1×10¹⁷ cm⁻³ to 1×10²⁰ cm⁻³ (more specifically, about 1×10¹⁸ cm⁻³). In addition, the substrate 2 may be a low-resistance GaN substrate, a low-resistance SiC substrate or the like, in addition to the low-resistance silicon substrate. The substrate 2 is electrically connected to the source electrode 8.

The buffer layer 3 includes by a multilayer buffer layer obtained by stacking a plurality of nitride semiconductor films. In the present embodiment, the buffer layer 3 includes a first buffer layer 31 constituted by an AlN film which is in contact with the surface of the substrate 2, and a second buffer layer 32 constituted by an AlGaN film stacked on the surface of the first buffer layer 31 (the opposite surface of the substrate 2). The thickness of the first buffer layer 31 is, for example, 0.2 μm, and the thickness of the second buffer layer 32 is, for example, 0.12 μm. The buffer layer 3 may be constituted by, for example, a single AlN film.

The electron transit layer 4 includes a first nitride semiconductor layer 41 formed on the buffer layer 3, and a second nitride semiconductor layer 42 which is formed on the first nitride semiconductor layer 41 and in which a two-dimensional (2D) electron gas 10 is formed. An upper surface of the second nitride semiconductor layer 42 is in contact with a lower surface of the electron supply layer 5. The first nitride semiconductor layer 41 is an example of the “nitride semiconductor layer” of the present disclosure, and the second nitride semiconductor layer 42 is an example of a “conduction path forming layer” in the present disclosure.

The first nitride semiconductor layer 41 is a semiconductor layer including a large amount of acceptor impurity, while the second nitride semiconductor layer 42 is a semiconductor layer including little acceptor impurity. In the present embodiment, the first nitride semiconductor layer 41 is constituted by a GaN layer doped with an acceptor type impurity. The thickness of the first nitride semiconductor layer 41 is about 0.5 to 2.0 μm. In the present embodiment, the acceptor type impurity is carbon (C). In the present embodiment, a concentration of carbon, which is the acceptor type impurity, is about 4×10¹⁹ cm⁻³. The concentration of carbon, which is the acceptor type impurity, is preferably 1×10¹⁹ cm⁻³ or more and 8×10¹⁹ cm⁻³ or less. The reason for this will be described later.

When GaN is doped with carbon, a deep acceptor (DD) level is formed in GaN. Further, when GaN is doped with carbon, a vacancy defect VGa(VN)n including one gallium vacancy and two nitrogen vacancies is generated in the GaN, and this vacancy defect VGa(VN)n acts as the deep donor (DD) level. A deep donor density NDD of the first nitride semiconductor layer 41 is higher than a deep acceptor density NDA of the first nitride semiconductor layer 41. The reason for this is that current collapse can be suppressed. Details of this reason will be described later.

In the present embodiment, the second nitride semiconductor layer (conduction path forming layer) 42 is constituted by a GaN layer including little acceptor impurity, and has a thickness of about 0.1 μm. The electron supply layer 5 is constituted by a nitride semiconductor having a band gap larger than that of the electron transit layer 4. Specifically, the electron supply layer 5 is constituted by a nitride semiconductor having an Al composition higher than that of the electron transit layer 4. In the nitride semiconductors, the higher the Al composition is, the larger the bad gap becomes. In the present embodiment, the electron supply layer 5 is constituted by an Alₓ₁Ga₁₋ₓ₁N layer (0<x1<1) and has a thickness of about 10 nm. The thickness of the electron supply layer 5 is preferably 10 nm or more and 20 nm or less.

In this manner, the electron transit layer 4 and the electron supply layer 5 are constituted by nitride semiconductors having different band gaps (Al compositions), and lattice mismatch occurs therebetween. Further, an energy level of the conduction band of the electron transit layer 4 at the interface between the electron transit layer 4 and the electron supply layer 5 due to spontaneous polarization of the electron transit layer 4 and the electron supply layer 5 and piezo polarization caused by the lattice mismatch therebetween becomes lower than the Fermi level. Therefore, the 2D electron gas (2DEG) 10 is spread in the second nitride semiconductor layer 42 at a position close to the interface between the electron transit layer 4 and the electron supply layer 5 (for example, a distance of several Å from the interface).

The gate electrode 6 is formed in contact with the electron supply layer 5. In the present embodiment, the gate electrode 6 is constituted by a TiN layer and has a thickness of about 400 nm. The gate electrode 6 is disposed to be biased toward the source electrode contact hole 8a. The passivation film 7 is configured to cover a surface of the electron supply layer 5 (excluding a region where the contact holes 8a and 9a face) and a part of a side surface of the gate electrode 6. In this embodiment, the passivation film 7 is constituted by a SiN film and has a thickness of about 100 nm.

The source electrode 8 and the drain electrode 9 may include, for example, a lower layer in contact with the electron supply layer 5, an intermediate layer stacked on the lower layer, and an upper layer stacked on the intermediate layer. The lower layer may be Ti having a thickness of about 20 nm, the intermediate layer may be Al having a thickness of 200 nm, and the upper layer may be TiN having a thickness of about 50 nm. In this semiconductor device 1, the electron supply layer 5 having a different band gap (Al composition) is formed on the electron transit layer 4 to form a heterojunction. Thus, the 2D electron gas 10 is formed in the electron transit layer 4 near the interface between the electron transit layer 4 and the electron supply layer 5, and an HEMT is formed with the 2D electron gas 10 used as a channel. Thus, when no bias is applied to the gate electrode 6 (at the time of zero bias), since the source and the drain are electrically connected, this HEMT becomes a normally-on type device.

When an appropriate OFF voltage (e.g., −3 V) is applied to the gate electrode 62, since a depletion layer is formed immediately under the gate electrode 6, the electrical connection between the source and the drain is interrupted. When used, for example, a predetermined voltage (e.g., 200 to 300 V) is applied between the source electrode 8 and the drain electrode 9 so that the drain electrode 9 side becomes positive. In this state, an OFF voltage (−3 V) or an ON voltage (0 V) is applied to the gate electrode 6 with the source electrode 8 as a reference potential (0 V).

The reason that current collapse can be suppressed when the deep donor density NDD of the first nitride semiconductor layer 41 is larger than the deep acceptor density NDA of the first nitride semiconductor layer 41 will be described below. The cause of current collapse will be described by taking the semiconductor device 1 illustrated in FIG. 1B as an example. However, it is assumed here that the deep donor density NDD of the first nitride semiconductor layer 41 is smaller than the deep acceptor density NDA of the first nitride semiconductor layer 41.

The electron transit layer 4 constituted by GaN includes an unintended donor. When the electron transit layer 4 becomes an n-type, a leakage current may flow between the source electrode 8 and the drain electrode 9. Therefore, the electron transit layer 4 (particularly, the first nitride semiconductor layer 41) is doped with an acceptor type impurity (deep acceptor) for providing holes so that the electron transit layer 4 does not become an n-type. Electrons emitted from the donor are trapped by the deep acceptor, but since the deep acceptor density (trap density) NDA is larger than the deep donor density NDD, deep acceptors (vacant acceptors) which do not trap electrons exist in the electron transit layer 4. Deep acceptors trapping electrons are negatively charged.

When the semiconductor device 1 is turned off, a positive voltage is applied to the drain of the semiconductor device 1. When the semiconductor device 1 is turned on, the applied voltage to the drain of the semiconductor device 1 becomes low. When a positive voltage is applied to the drain of the semiconductor device 1, holes are emitted from the deep acceptors which do not trap electrons to a valence band on the side of the drain electrode 9 of the electron transit layer 4. That is, hole emission occurs. In other words, electrons from the valence band are trapped by the deep acceptors which do not trap electrons. Thus, a negative charge region (negatively charged region) in the electron transit layer 4 is enlarged. Since the 2D electron gas formed in the electron transit layer 4 repels the negative charge region, the 2D electron gas is reduced when the negative charge region in the electron transit layer 4 is widened. Thus, since the channel resistance increases, the drain current decreases. This phenomenon is called current collapse.

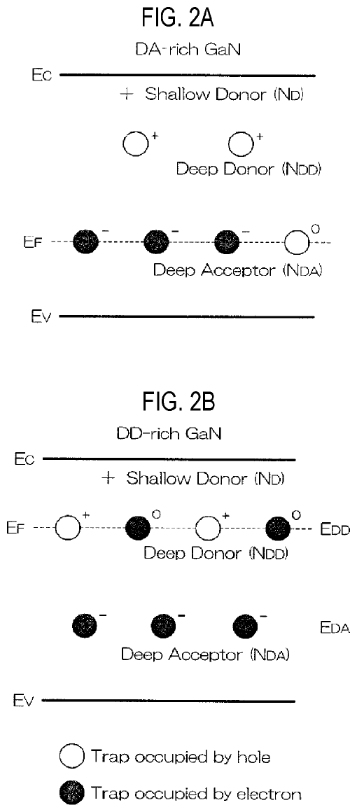

In the following description, a state where the deep acceptor density NDA is larger than the deep donor density NDD will be referred to as “DA-rich,” and a state where the deep donor density NDD is larger than the deep acceptor density NDA will be referred to as “DD-rich.” FIG. 2A is a schematic diagram for explaining a level in a band gap of DA-rich GaN, and FIG. 2B is a schematic diagram for explaining a level in a band gap of DD-rich GaN. In FIGS. 2A and 2B, “shallow donor” indicates a shallow donor. Further, EDD indicates a deep donor level, and EDA indicates a deep acceptor level.

In the DA-rich GaN, as illustrated in FIG. 2A, holes are trapped by all deep donors, but some of deep acceptors trap electrons and others do not trap electrons. The deep acceptors which trap the electrons (black circles) are negatively charged, and the deep acceptors which do not trap the electrons (white circles) are charge neutral. On the other hand, in the DD-rich GaN, as illustrated in FIG. 2B, electrons are trapped by all deep acceptors, but some deep donors trap and others do not trap electrons. Deep donors which trap electrons (black circles) are charge neutral, and deep donors which do not trap electrons (white circles) are positively charged.

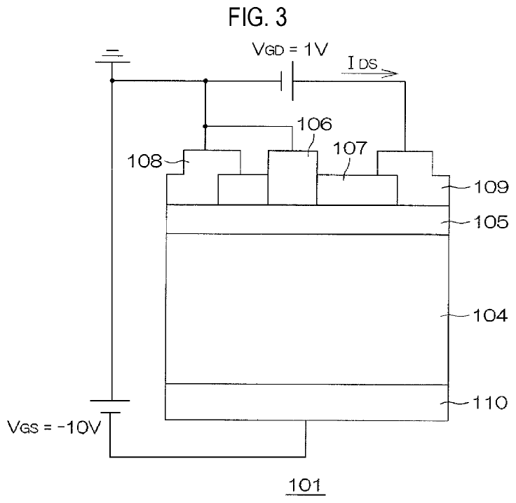

Further, in the related art, a deep donor level in the range of 0.5 eV to 0.7 eV is known for GaN. Simulation was conducted using a simulation model illustrated in FIG. 3 for comparison of the distribution of the conduction band lower end energy Ec and the temporal change of the source-drain current IDS when the first nitride semiconductor layer 41 is DA-rich and when the first nitride semiconductor layer 41 is DD-rich.

A simulation model 101 does not have a substrate, but has a configuration similar to that of the semiconductor device 1 in FIG. 1B. The simulation model 101 includes an electron transit layer 104, an electron supply layer 105 formed on the electron transit layer 104, a gate electrode 106, a source electrode 108 and a drain electrode 109 formed on the electron supply layer 105, a passivation film 107 formed on the electron supply layer 105, and a substrate electrode (back gate) 110 formed on a rear surface of the electron transit layer 104.

The electron transit layer 104, the electron supply layer 105, the gate electrode 106, the passivation film 107, the source electrode 108, and the drain electrode 109 correspond to the electron transit layer 4, the electron supply layer 5, the gate electrode 6, the passivation film 7, the source electrode 8, and the drain electrode 9 in FIG. 1B, respectively. However, in the simulation model 101, the electron transit layer 104 is formed of a nitride semiconductor layer set to semi-insulating GaN of DA-rich or a semi-insulating GaN of DD-rich.

In the semiconductor device 1 of FIG. 1B, when the semiconductor device 1 is turned off, a positive voltage of about 200 to 300 V is applied to the drain of the semiconductor device 1. In this simulation model 101, a voltage of 1 V is applied to the drain electrode 109 and a voltage of −10 V is applied to the substrate electrode 110, with the source electrode 108 as a reference potential (0 V), to form a state equivalent to a state where the positive high voltage is applied to a drain of the simulation model 101.

Specifically, first, the electron transit layer 104 was set to the DA-rich semi-insulating GaN. Then, the source electrode 108 and the gate electrode 106 were set to the reference potential (0 V), and an applied voltage VGD to the drain electrode 109 was set to 1 V. Then, a voltage VGS of −10 V was applied to the substrate electrode 110. Then, the distribution of the conduction band lower end energy Ec of the electron transit layer 104 and the temporal change after the start of voltage application of the source-drain current IDS were measured by simulation.

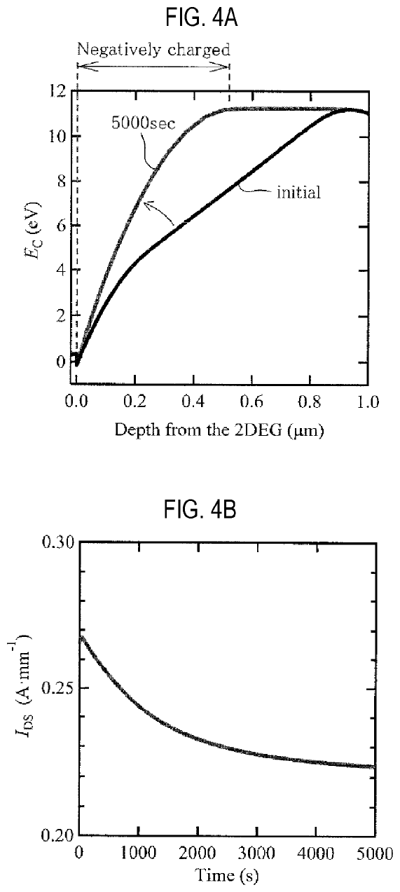

FIGS. 4A and 4B are graphs illustrating simulation results when the electronic transit layer is set to DA-rich. FIG. 4A is a graph illustrating a temporal change in distribution of a conduction band lower end energy Ec [eV] to a depth [μm] of the electron transit layer 104. The depth of the electron transit layer 104 is expressed by the distance from the surface of the electron transit layer 104 on the electron supply layer 105 side.

A curve (initial) in FIG. 4A indicates a distribution of the conduction band lower end energy EC to the depth of the electron transit layer 104 before applying a bias of −10 V to the substrate electrode 110. A curve (5,000 sec) in FIG. 4A indicates a distribution of the conduction band lower end energy EC to the depth of the electron transit layer 104 after 5,000 seconds have elapsed since the bias of −10 V was applied to the substrate electrode 110.

FIG. 4B is a graph illustrating a temporal change in the source-drain current IDS after applying a bias of −10 V to the substrate electrode 110. When the electron transit layer 104 is DA-rich, deep acceptors which do not trap electrons exist in the electron transit layer 104 (see FIG. 2A). Therefore, when a voltage of −10 V is applied to the substrate electrode 110, hole emission (electron trap from the valence band) occurs on the positive bias side (2DEG side of the electron transit layer 104). When deep acceptors trap the electrons, since they are negatively charged, a negative charge region is formed on the 2DEG side of the electron transit layer 104.

Accordingly, as indicated by an arrow in FIG. 4A, the distribution of the conduction band lower end energy EC to the depth of the electron transit layer 104 is changed so that the conduction band lower end energy EC at the center of the depth of the electron transit layer 104 is increased over time. Therefore, since the 2D electron gas density is reduced, the source-drain current IDS decreases over time, as illustrated in FIG. 4B. That is, when the electron transit layer 104 is DA-rich, the current collapse occurs.

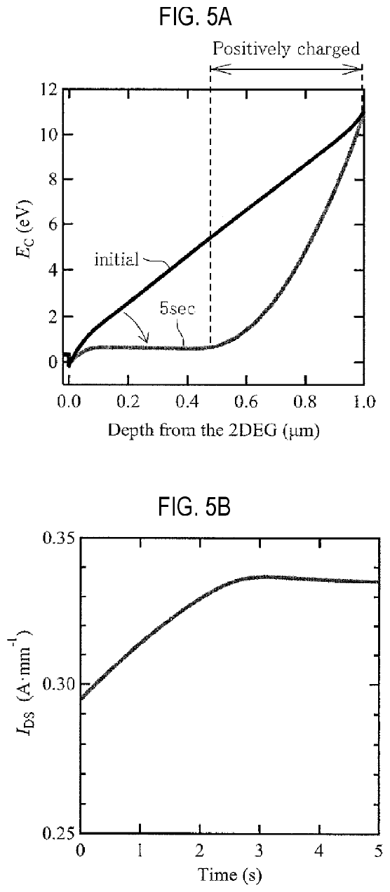

Next, the electron transit layer 104 is set to a DD-rich semi-insulating GaN, and in the same manner, the distribution of the conduction band lower end energy Ec of the electron transit layer 104 and the temporal change after the start of voltage application of the source-drain current IDS were measured by simulation. FIGS. 5A and 5B are graphs illustrating simulation results when the electron transit layer is set to DD-rich.

FIG. 5A is a graph illustrating a temporal change in distribution of a conduction band lower end energy Ec [eV] to a depth [μm] of the electron transit layer 104. A curve (initial) in FIG. 5A indicates a distribution of the conduction band lower end energy EC to the depth of the electron transit layer 104 before applying a bias of −10 V to the substrate electrode 110. A curve (5 sec) in FIG. 5A indicates a distribution of the conduction band lower end energy EC to the depth of the electron transit layer 104 after 5 seconds have elapsed since the bias of −10 V was applied to the substrate electrode 110.

FIG. 5B is a graph illustrating a temporal change in the source-drain current IDS after a bias of −10 V is applied to the substrate electrode 110. When the electron transit layer 104 is DD-rich, deep donors which trap electrons exist in the electron transit layer 104 (see FIG. 2B). Therefore, when a voltage of −10 V is applied to the substrate electrode 110, electron emission (electron emission to the conduction band) occurs on the negative bias side (substrate side of the electron transit layer 104). Since the deep donors which have emitted electrons are positively charged, a positive charge region (positively charged region) is formed on the substrate side of the electron transit layer 104.

Accordingly, as indicated by an arrow in FIG. 5A, the distribution of the conduction band lower end energy EC to the depth of the electron transit layer 104 changes so that the conduction band lower end energy EC at the center of the depth of the electron transit layer 104 decreases over time. Therefore, since the 2D electron gas density increases, the source-drain current IDS is increased over time, as illustrated in FIG. 5B.

That is, it can be understood that, when the electron transit layer 104 is DD-rich, current collapse can be suppressed. Thus, in the semiconductor device 1 of FIG. 1B, it can be understood that, when the deep donor density NDD of the first nitride semiconductor layer 41 is larger than the deep acceptor density NDA of the first nitride semiconductor layer 41, the current collapse can be suppressed. Next, three samples differing only in the carbon concentration of the first nitride semiconductor layer 41 were prepared. Carbon concentrations [C] of the first nitride semiconductor layer 41 of a first sample, a second sample, and a third sample are as follows:

First sample: [C]=5×10¹⁷ cm⁻³

Second sample: [C]=5×10¹⁸ cm⁻³

Sample S3: [C]=4×10¹⁹ cm⁻³.

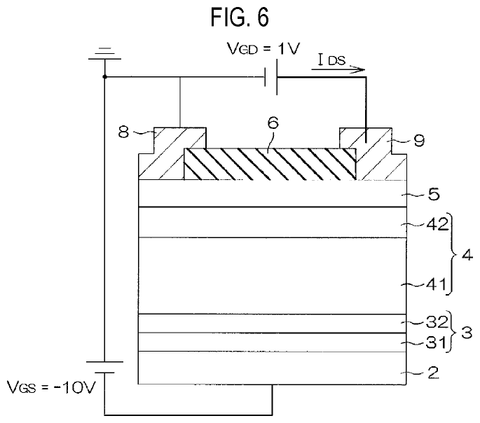

FIG. 6 is a cross-sectional view illustrating a configuration of each sample. In FIG. 6, parts corresponding to the respective parts in FIG. 1B described above are denoted by the same reference numerals as in FIG. 1B. Each sample is the same except that the carbon density of the first nitride semiconductor layer 41 is different.

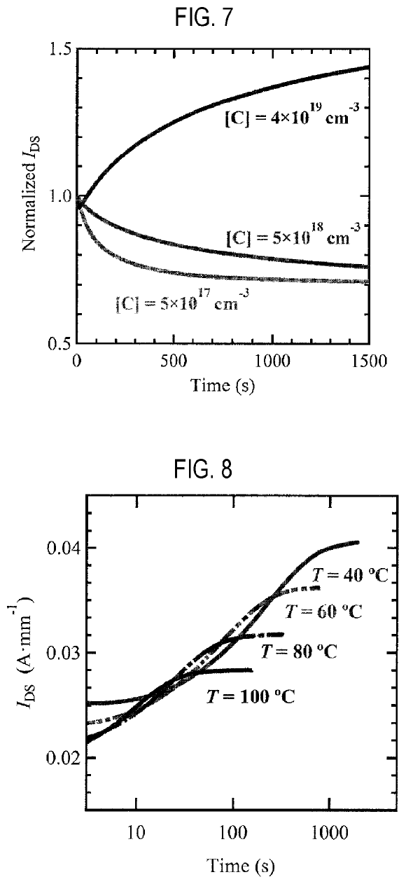

First, an experiment for measuring the source-drain current IDS was performed on each sample. Specifically, as illustrated in FIG. 6, a voltage VGS of −10 V was applied to the substrate 2 with a voltage VGD of 1 V applied to the drain electrode 9 using the source electrode 8 as the reference potential (0 V). Then, the source-drain current IDS was measured. FIG. 7 is a graph illustrating an experimental result. In the graph of FIG. 7, the horizontal axis indicates an elapsed time [s] after applying −10 V to the substrate 2 of each sample, and the vertical axis indicates a normalized source-drain current IDS. The normalized source-drain current IDS is a value obtained by normalizing the source-drain current IDS so that the source-drain current IDS immediately before applying −10 V to the substrate 2 of each sample becomes a reference value (1.0).

In the first sample ([C]=5×10¹⁷ cm⁻³) and the second sample ([C]=5×10¹⁸ cm⁻³), the normalized source-drain current IDS decreased over time. That is, in the cases where the carbon concentration of the first nitride semiconductor layer 41 is 5×10¹⁷ cm⁻³ and 5×10¹⁸ cm⁻³, it can be estimated that the first nitride semiconductor layer 41 is DA-rich.

On the other hand, in the third sample ([C]=4×10¹⁹ cm⁻³), the normalized source-drain current IDS increased over time. That is, when the carbon concentration of the first nitride semiconductor layer 41 is 4×10¹⁹ cm⁻³, it can be estimated that the first nitride semiconductor layer 41 is DD-rich. The same experiment as described above was performed on the third sample under a plurality of different temperature environments. Specifically, the same experiment as described above was performed on the third sample under four kinds of temperature environments of 40 degrees C., 60 degrees C., 80 degrees C., and 100 degrees C.

FIG. 8 is a graph illustrating an experimental result. In the graph of FIG. 8, the horizontal axis indicates an elapsed time [s] after applying −10 V to the substrate 2 of the third sample, and the vertical axis indicates a source-drain current IDS [A·mm−1], where T denotes an ambient temperature. The source-drain current IDS increases over time under any temperature environment. Specifically, the source-drain current IDS increases gradually at first and then increases rapidly. Thereafter, the source-drain current IDS increases gradually.

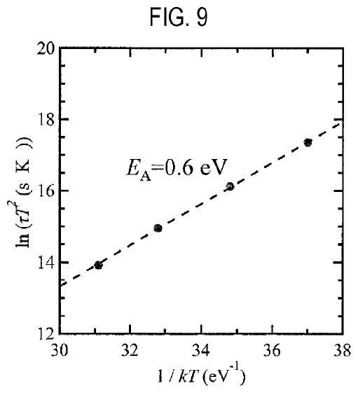

In the time-source-drain current characteristics under each temperature environment, the time from when −10 V is applied to the substrate 2 to when the slope of a characteristic curve (current change over time) becomes maximum is defined as a time constant τ. Performing the Arrhenius plotting on the time constant τ to the ambient temperature T by taking 1/kT [eV⁻¹] on the horizontal axis and taking a logarithm of τ·T2 (In (τ·T2 [sK])) on the vertical axis yields a straight line as indicated by a broken line in FIG. 9, where k is a Holzman constant and K is Kelvin.

When an activation energy EA is obtained from the slop of the straight line in FIG. 9, EA was a value within the range of 0.5 eV to 0.7 eV, specifically about 0.6 eV. That is, the activation energy of the temperature characteristics of the source-drain current (resistance change rate) in the third sample coincided with the generally reported deep donor level (0.5 eV to 0.7 eV). Therefore, it can be presumed that the first nitride semiconductor layer 41 of the third sample became DD-rich.

Next, an experiment for measuring an on-resistance was performed on each sample. Specifically, as illustrated in FIG. 6, the on-resistance was measured by applying a voltage VGS of −10 V to the substrate 2 for 1,000 seconds and then setting the applied voltage to the substrate 2 to 0 V with a voltage VGD of 1 V applied to the drain electrode 9 using the source electrode 8 as the reference potential (0 V). Further, the same experiment was performed with the applied voltage VGS to the substrate 2 set to −20 V, −30 V, −40 V, −50 V, −60 V, and −70 V.

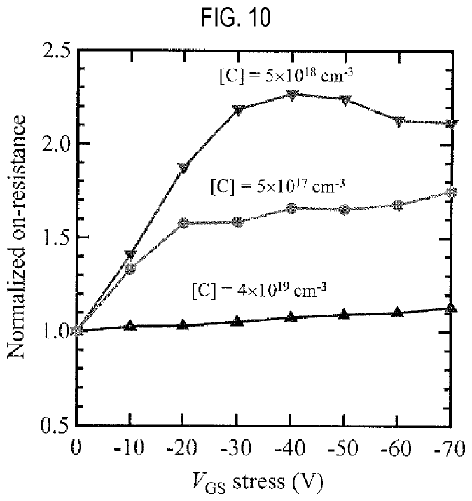

FIG. 10 is a graph illustrating an experimental result. In the graph of FIG. 10, the horizontal axis indicates an applied voltage VGS [V] to the substrate 2 of each sample, and the vertical axis indicates a normalized on-resistance. The normalized on-resistance is a value obtained by normalizing the on-resistance so that the on-resistance immediately before applying the negative bias VGS to the substrate 2 of each sample becomes the reference value (1.0). In the first sample ([C]=5×10¹⁷ cm⁻³) and the second sample ([C]=5×10¹⁸ cm⁻³), the normalized on-resistance after applying the negative bias VGS for 1,000 seconds was larger than the normalized on-resistance before applying the negative bias, regardless of the negative bias VGS applied to the substrate 2. That is, it can be seen that the current collapse occurs in the first sample and the second sample.

On the other hand, in the third sample ([C]=4×10¹⁹ cm⁻³), the normalized on-resistance after applying the negative bias VGS for 1,000 seconds is slightly increased compared with the normalized on-resistance before applying the negative bias, regardless of the negative bias VGS applied to the substrate 2, but it can be seen that the increase is extremely small compared with the first and second samples. That is, it can be seen that the current collapse is suppressed in the third sample compared with the first and second samples.

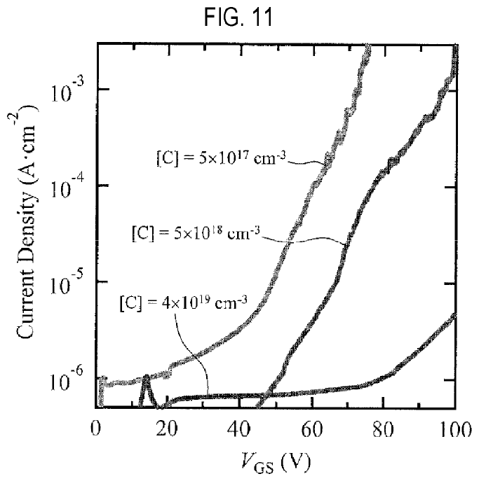

Next, an experiment for measuring a vertical leakage current was performed on each sample. Specifically, the vertical leakage current (current density) [A·cm²] was measured by applying the positive bias VGS to the substrate 2, with the voltage VGD of 1 V applied to the drain electrode 9 using the source electrode 8 as the reference potential (0 V). FIG. 11 is a graph illustrating an experimental result. In the first sample ([C]=5×10¹⁷ cm⁻³) and the second sample ([C]=5×10¹⁸ cm⁻³), the vertical leakage current increased as the positive bias VGS applied to the substrate 2 increased.

On the other hand, in the third sample ([C]=4×10¹⁹ cm⁻³), when the positive bias VGS applied to the substrate 2 increased, the vertical leakage current once increased and then decreased to almost zero in a range where the positive bias VGS applied to the substrate 2 is 12 to 18V. Thereafter, as the positive bias VGS applied to the substrate 2 increased, the vertical leakage current increased. However, in a range where the positive bias VGS applied to the substrate 2 is 50 V or more, it can be seen that the vertical leakage current to the positive bias VGS in the third sample is extremely higher than the vertical leakage current in the first and second samples. That is, it can be seen that the vertical leakage current is suppressed in the third sample compared with the first and second samples.

It can be seen from the above that, when the carbon concentration of the first nitride semiconductor layer 41 is 4×10¹⁹ cm⁻³ as in the present embodiment, the first nitride semiconductor layer 41 becomes DD-rich and the current collapse and the vertical leakage current are suppressed. Next, the reason that the carbon concentration of the first nitride semiconductor layer 41 is preferably 1×10¹⁹ cm⁻³ or more and 8×10¹⁹ cm⁻³ or less will be described.

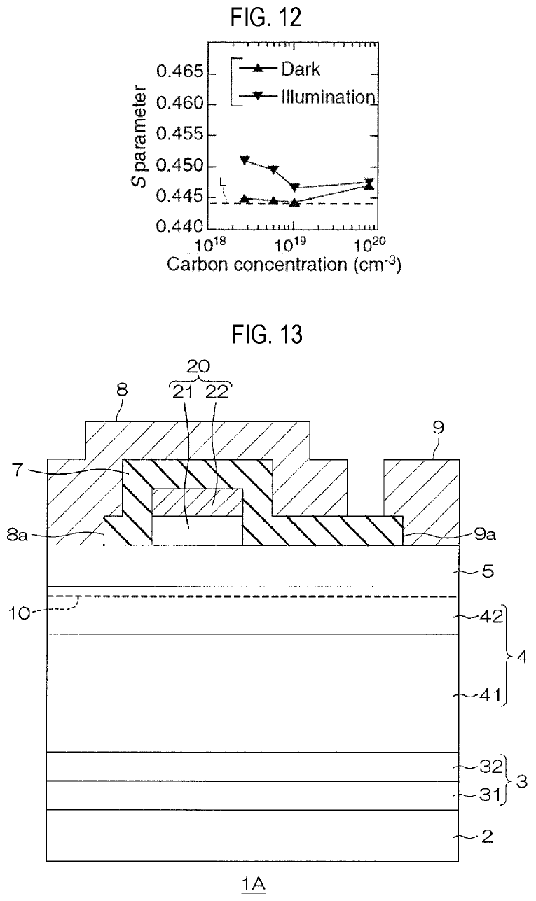

FIG. 12 is a graph illustrating a result of measuring an S parameter by a positron annihilation method for GaN samples having different carbon densities. In FIG. 12, a broken line (Dark) is a graph illustrating a measurement result when the S parameter is measured without irradiating a sample with light, and a broken line (Illumination) is a graph illustrating a measurement result when the S parameter is measured when a sample irradiated with light. In FIG. 12, a broken line L indicates an S parameter of GaN having no vacancy defect. The S parameter of GaN having no vacancy defect is obtained by simulation.

The positron annihilation method is a method for detecting a vacancy defect in a substance using positrons with positive charges. Therefore, even if there is a vacancy defect in GaN, when the vacancy defect is positively charged, it will repel against positrons, making it impossible to detect the vacancy defect. Therefore, as illustrated in FIG. 2A described above, when GaN is DA-rich, since the vacancy defect acting as deep donors is positively charged, the vacancy defect cannot be detected by an electron annihilation method. That is, when GaN is DA-rich, the S parameter measured by the positron annihilation method is considered to be a value close to the S parameter of GaN having no vacancy defect.

However, when the sample is irradiated with light, the positively charged vacancy defect is neutralized. Therefore, even when GaN is DA-rich, the vacancy defect can be detected. On the other hand, as illustrated in FIG. 2B described above, when GaN is DD-rich, since the vacancy defect acting as deep donors includes an electrically neutral vacancy defect, the vacancy defect can be detected by the electron annihilation method.

It is considered that as the carbon concentration of GaN is increased, the vacancy defect acting as deep donors is increased. Furthermore, from the broken lines (Dark and Illumination) in FIG. 12, when the carbon concentration of GaN is 5×10¹⁸ cm⁻³ or more and less than 1×10¹⁹ cm⁻³, it can be seen that the vacancy defect can be detected when the sample is irradiated with light, but the vacancy defect cannot be detected when the sample is not irradiated with light. That is, when the carbon concentration is 5×10¹⁸ cm⁻³ to 1×10¹⁹ cm⁻³, it can be seen that the vacancy defect exists, but this vacancy defect is positively charged. When the carbon concentration is 1×10¹⁹ cm⁻³ or more, it can be seen that the vacancy defect can be detected even when the sample is not irradiated with light.

Thus, it can be determined that the carbon concentration of 1×10¹⁹ cm⁻³ is the carbon concentration at the boundary of whether or not the vacancy defect acting as deep donors is charge-neutralized. Therefore, when the carbon density is 1×10¹⁹ cm⁻³ or more, it can be determined that the vacancy defect is charge-neutralized. That is, when the carbon density is 1×10¹⁹ cm⁻³ or more, it can be determined that GaN becomes DD-rich.

On the other hand, an upper limit value of the carbon density capable of stably doping carbon into GaN is usually about 8×10¹⁹ cm⁻³. Therefore, in order to make the first nitride semiconductor layer 41 DD-rich and suppress current collapse, it is preferable that the carbon density of the first nitride semiconductor layer 41 be set to 1×10¹⁹ cm⁻³ or more and 8×10¹⁹ cm⁻³ or less. In the aforementioned embodiment, there has been described a case where the present disclosure is applied to the normally-on type semiconductor device, but the present disclosure may also be applied to a normally-off type semiconductor device.

FIG. 13 is a cross-sectional view illustrating a configuration example of a normally-off type semiconductor device 1A to which the present disclosure is applied. In FIG. 13, parts corresponding to the respective parts in FIG. 1B described above are denoted by the same reference numerals as in FIG. 1B. The semiconductor device 1 includes a substrate 2, a buffer layer 3 formed on a surface of the substrate 2, an electron transit layer 4 constituted by a nitride semiconductor layer epitaxially grown on the buffer layer 3, an electron supply layer 5 constituted by a nitride semiconductor layer epitaxially grown on the electron transit layer 4, and a gate part 20 formed on the electron supply layer 5. The gate part 20 includes a nitride semiconductor layer 21 epitaxially grown on the electron supply layer 5 and a gate electrode 22 formed on the nitride semiconductor layer 21.

In addition, the semiconductor device 1A includes a passivation film 7 configured to cover the electron supply layer 5 and the gate part 20. Further, the semiconductor device 1A includes a source electrode 8 and a drain electrode 9 which are in ohmic contact with the electron supply layer 5 through a source electrode contact hole 8a and a drain electrode contact hole 9a formed in the passivation film 7. The source electrode 8 and the drain electrode 9 are arranged at an interval. The source electrode 8 is formed so as to cover the gate part 20.

The configurations, materials, and thicknesses of the substrate 2, the buffer layer 3, the electron transit layer 4, and the electron supply layer 5 are respectively identical to those of the substrate 2, the buffer layer 3, the electron transit layer 4, and the electron supply layer 5 in FIG. 1B. The electron transit layer 4 is constituted by a first nitride semiconductor layer 41 and a second nitride semiconductor layer 42 as in the semiconductor device 1 of FIG. 1B. Further, the deep donor density NDD of the first nitride semiconductor layer 41 is higher than the deep acceptor density NDA of the first nitride semiconductor layer 41.

The nitride semiconductor layer 21 constituting a part of the gate part 20 is made of a nitride semiconductor doped with an acceptor type impurity. In the present embodiment, the nitride semiconductor layer 21 is constituted by a GaN layer doped with the acceptor type impurity (p-type GaN layer) and has a thickness of about 60 nm. The concentration of the acceptor type impurity is preferably 3×10¹⁷ cm⁻³ or more. In this embodiment, the acceptor type impurity is magnesium (Mg). The acceptor type impurity may be an acceptor type impurity other than Mg, such as carbon (C) or the like. The nitride semiconductor layer 21 is installed to cancel a 2D electron gas 10 generated at the interface between the electron transit layer 4 and the electron supply layer 5 in a region immediately under the gate part 20.

The gate electrode 22 is formed so as to be in contact with the nitride semiconductor layer 21. In the present embodiment, the gate electrode 22 is constituted by a TiN layer and has a thickness of about 100 nm. The gate electrode 22 is disposed to be biased toward the source electrode contact hole 8a. The passivation film 7 is configured to cover the surface of the electron supply layer 5 (excluding a region where the contact holes 9a and 10a face), the side surface of the nitride semiconductor layer 61, and the side surface and front surface of the gate electrode 22. In this embodiment, the passivation film 7 is constituted by a SiN film and has a thickness of about 100 nm.

In this semiconductor device 1A, the electron supply layer 5 having a different band gap (Al composition) is formed on the electron transit layer 4 to form a heterojunction. Therefore, a 2D electron gas 10 is formed in the electron transit layer 4 near the interface between the electron transit layer 4 and the electron supply layer 5, and an HEMT is formed with the 2D electron gas 10 used as a channel. The gate electrode 22 faces the electron supply layer 5 with the nitride semiconductor layer 21 constituted by a p-type GaN layer interposed therebetween. Energy levels of the electron transit layer 4 and the electron supply layer 5 are increased by an ionization acceptor included in the nitride semiconductor layer 21 constituted by the p-type GaN layer under the gate electrode 22, and therefore, an energy level of a conduction band at a heterojunction interface becomes higher than the Fermi rank. Therefore, the 2D electron gas 10 caused by spontaneous polarization of the electron transit layer 4 and the electron supply layer 5 and piezoelectric polarization due to their lattice mismatch is not formed immediately under the gate electrode 22 (gate part 20). Thus, when no bias is applied to the gate electrode 22 (at the time of zero bias), the channel formed by the 2D electron gas 10 is cut off immediately under the gate electrode 22. In this manner, the normally-off type HEMT is realized. When an appropriate ON voltage (e.g., 3 V) is applied to the gate electrode 22, the channel is induced in the electron transit layer 4 immediately under the gate electrode 22, and the 2D electron gas 10 on both sides of the gate electrode 22 is connected thereto. Thus, the source and drain are electrically connected.

When used, for example, a predetermined voltage (e.g., 200 to 300 V) is applied between the source electrode 8 and the drain electrode 9 so that the drain electrode 9 becomes positive. In this state, an OFF voltage (0 V) or an ON voltage (3 V) is applied to the gate electrode 22 with the source electrode 8 as a reference potential (0 V). Even in the semiconductor device 1A, the current collapse can be suppressed as in the semiconductor device 1 described above.

Although the embodiment of the present disclosure has been described above, the present disclosure may also be implemented in other embodiments. For example, in the aforementioned embodiment, the silicon is exemplified as a material example of the substrate 2, but any other substrate material such as a sapphire substrate or a GaN substrate may be applied.

According to the present disclosure in some embodiments, it is possible to suppress the current collapse.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a conductive substrate;
an electron transit layer arranged on the conductive substrate;
an electron supply layer arranged on the electron transit layer; and
a source electrode, a drain electrode, and a gate electrode arranged on the electron supply layer,
wherein the electron transit layer includes a nitride semiconductor layer including an acceptor type impurity, and
wherein the semiconductor device has a characteristic that when a negative bias is applied to the conductive substrate, a source-drain resistance decreases over time.

2. A semiconductor device, comprising:
a substrate;
an electron transit layer arranged on the substrate;
an electron supply layer arranged on the electron transit layer; and
a source electrode, a drain electrode, and a gate electrode arranged on the electron supply layer,
wherein the electron transit layer includes a nitride semiconductor layer including an acceptor type impurity, and
wherein a deep donor density of the nitride semiconductor layer is larger than a deep acceptor density of the nitride semiconductor layer.

3. The device of claim 1, wherein the electron transit layer includes the nitride semiconductor layer, and a conduction path forming layer which is formed between the nitride semiconductor layer and the electron supply layer and whose surface is in contact with the electron supply layer.

4. The device of claim 1, wherein an activation energy of a temperature characteristic of a source-drain resistance change rate is 0.5 eV or more and 0.7 eV or less.

5. The device of claim 1, wherein a deep donor level of the nitride semiconductor layer is within a range of 0.5 eV or more and 0.7 eV or less from a conduction band.

6. The device of claim 1, wherein the acceptor type impurity is carbon, and a carbon density of the nitride semiconductor layer is 1×10¹⁹ cm⁻³ or more and 8×10¹⁹ cm⁻³ or less.

7. The device of claim 1, wherein the nitride semiconductor layer includes a vacancy defect VGa(VN)n including one gallium vacancy and two nitrogen vacancies.

8. A semiconductor device, comprising:
a substrate;
an electron transit layer arranged on the substrate;
an electron supply layer arranged on the electron transit layer; and
a source electrode, a drain electrode, and a gate electrode arranged on the electron supply layer,
wherein the electron transit layer includes a nitride semiconductor layer including an acceptor type impurity, and
wherein the acceptor type impurity is carbon, and a carbon density of the nitride semiconductor layer is 1×10¹⁹ cm⁻³ or more and 8×10¹⁹ cm⁻³ or less.
